(19) United States
(12) Patent Application Publication
(10) Pub. No.: US 2010/0243310 A1
(43) Pub. Date: Sep. 30, 2010

(54) PRINTED CIRCUIT BOARD

(75) Inventors: YU-CHANG PAI, Tu-Cheng (TW); CHIEN-HUNG LIU, Tu-Cheng (TW); PO-CHUAN HSIEH, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/430,131

(22) Filed: Apr. 27, 2009

(30) Foreign Application Priority Data
Mar. 26, 2009 (CN) 200910301151.X

(51) Int. Cl. H05K 1/11

(52) U.S. Cl. 174/266

(57) ABSTRACT

A printed circuit board (PCB) includes a power layer, a ground layer, a through hole, and a conductor. The through hole goes through the power layer and the ground layer. The conductor includes a hollow columnar main body and an extending portion. The main body is formed in a bounding wall of the through hole, and is conductively connected to one of the power layer and the ground layer, and insulated from the other one of the power layer and the ground layer by an insulation area. The extending portion extends out from the circumferential surface of the main body. The extending portion extends into the insulation area and is insulated from the other one of the power layer and the ground layer, to increase an area of the power layer facing the ground layer.

### BACKGROUND

1. Technical Field

The present disclosure relates to printed circuit boards (PCBs), and particularly to a PCB having a stable output voltage.

2. Description of the Related Art

Generally, a plurality of decoupling capacitors are deployed between power through holes and ground through holes of a PCB to increase capacitance of the PCB. With capacitance of the PCB increasing, input impedances of alternating current (AC) power supplies on the PCB decrease. Thus, the AC power supplies have stable output voltages. Although single decoupling capacitors are relatively inexpensive, PCB cost increases when increasing the number of decoupling capacitors.

### BRIEF DESCRIPTION OF THE DRAWINGS

FIG. 1 is a schematic diagram of an exemplary embodiment of a PCB.

FIG. 2 is block diagram of an electrical conductor in FIG. 1.

FIG. 3 is a wave diagram of one embodiment of input impedances of AC power supplies on the PCB in FIG. 1 and on a traditional PCB.

### DETAILED DESCRIPTION

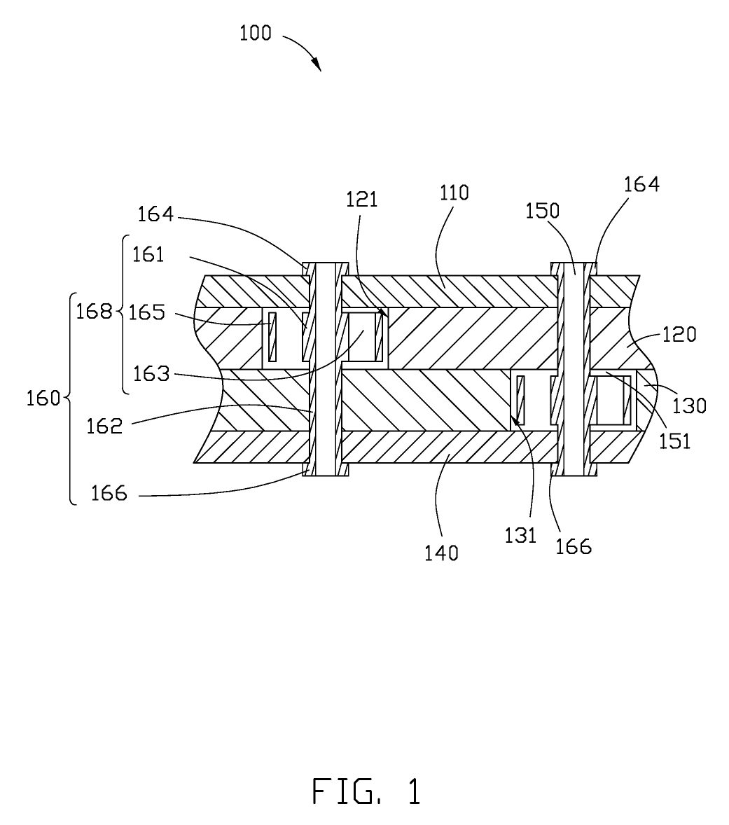

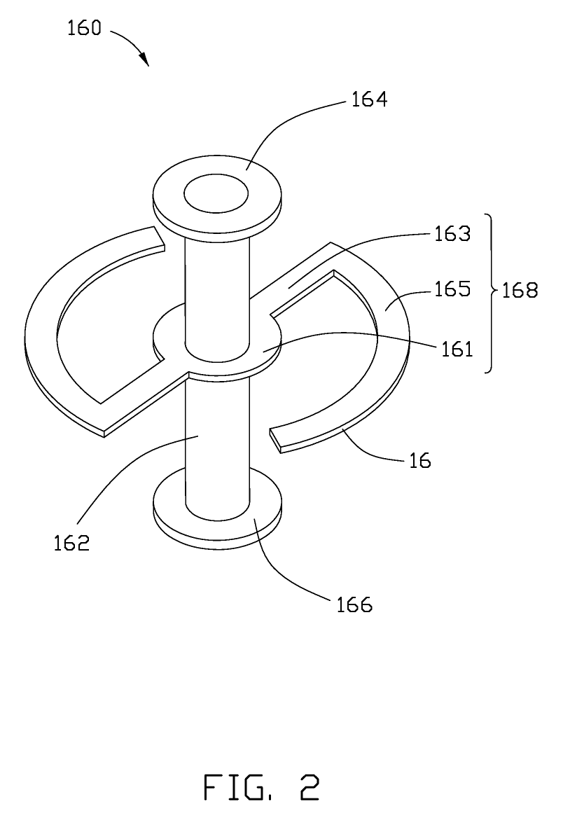

Referring to FIGS. 1-2, an exemplary embodiment of a PCB 100 includes a first signal layer 110, a power layer 120, a ground layer 130, a second signal layer 140, a plurality of through holes 150, and a plurality of electrical conductors 160. The first signal layer 110, the power layer 120, the ground layer 130, and the second signal layer 140 are deployed in a top-down model. Each through hole 150 goes through the signal layer 110, the power layer 120, the ground layer 130, and the second signal layer 140. Each electrical conductor 160 surrounds a through hole 150.

Each electrical conductor 160 includes a hollow columnar main portion 162 formed on a bounding wall of the through hole 150, two pads 164, 166, and an extending portion 168. The main portion 162 is conductively connected to one of the power layer 120 and the ground layer 130, and insulated from the other one of the power layer 120 and the ground layer 130 by an insulation area 151. The extending portion 168 extends into the insulation area 151 but is still insulated from the other one of the power layer 120 and the ground layer 130. If the extending portion 168 is insulated from the power layer 120 and electrically connected to the ground layer 130, an outer face 16 of the extending part 165 faces to an inner surface 121 of the power layer 120, to increase an area of the ground layer 130 facing the power layer 120. If the extending portion 168 is insulated from the ground layer 130 and electrically connected to the power layer 120, the outer face 16 of the extending part 165 faces to an inner surface 131 of the ground layer 130, to increase an area of the power layer 120 facing the ground layer 130. Thus, capacitance between the power layer 120 and the ground layer 130 increases by deploying the extending portion 168 in the insulation area 151. It should be understood that the thickness of the extending part 165 is substantially equal to the thickness of the power layer 120 or the ground layer 130 to increase the capacitance between the power layer 120 and the ground layer 130.

Each through hole 150 is defined in a hollow columnar main portion 162. The pads 164, 166 are deployed on the first and second signal layer 110, 140 respectively, communicating with the corresponding through hole 150. The extending portion 168 extends out from the circumferential surface of the hollow columnar main portion 162. If the through hole 150 in the hollow columnar main portion 162 is a power through hole, the extending portion 168 is separated from the ground layer 130 by an insulation area 151. If the through hole 150 in the hollow columnar main portion 162 is a ground through hole, the extending portion 168 is separated from the power layer 120 by another insulation area 151. The electrical conductor 160 is made of conductive material, such as copper foil, for example.

The extending portion 168 includes a central part 161 with a ring-shape, two linking parts 163, and two extending part 165. The central part 161 is located around the hollow columnar main portion 162. The linking parts 163 extend out from the central part 161. The extending parts 165 extend from distal ends of the linking parts 163. The outer diameter of the central part 161 can be substantially equal to the outer diameter of each of the pads 164, 166. The extending part 165 is located on a circle having an outer diameter greater than the outer diameter of the central part 161. The central part 161, the linking part 163, and the extending part 165 are used for increasing an area of the power layer 120 facing the ground layer 130 to increase the capacitance of the PCB 100. Thus, input impedances of AC power supplies on the PCB 100 are reduced to stable output voltages of the AC power supplies. It should be understood that structures of the hollow columnar main portion 162 and the central part 161, and the number of the linking part 163 and the extending part 165 can be adjusted depending on embodiments.

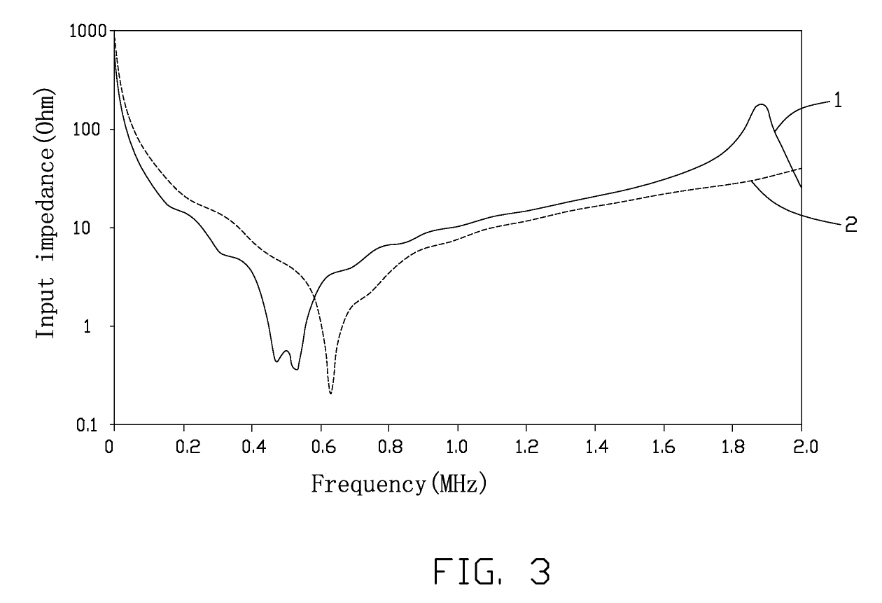

Referring to FIG. 3, when a frequency is lower than 0.6 MHZ, input impedances of the AC power supplies on the PCB 100, shown as a wave diagram 1, are observably less than input impedances of AC power supplies on a traditional PCB without the extending portion 168, shown as a wave diagram 2. It is understood that the size and structure of the central part 161, the linking part 163, and the extending part 165 can be adjusted to increase the area of the power layer 120 facing the ground layer 130. Furthermore, the extending portion 168 can extend from the power layer 120 and the ground layer 130, and is separated from the hollow columnar main portion 162 by the insulation area 151 to achieve the purpose of the disclosure. Accordingly, the extending portion 168 is made of conductive material such as copper.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A printed circuit board (PCB) comprising:
a power layer;
a ground layer;
a through hole, wherein the through hole goes through the power layer and the ground layer; and a conductor comprising a hollow main body formed in a bounding wall of the through hole, and an extending portion extending out from the circumferential surface of the main body, wherein the hollow main body is conductively connected to one of the power layer and the ground layer, and insulated from the other one of the power layer and the ground layer by an insulation area, the extending portion extends into the insulation area and is insulated from the other one of the power layer and the ground layer, to increase an area of the power layer facing the ground layer.

2. The PCB of claim 1, wherein the through hole is a power through hole or a ground through hole.

3. The PCB of claim 1, wherein the conductor is made of copper foil.

4. The PCB of claim 1, wherein the conductor is made of copper.

5. The PCB of claim 1, further comprising a first signal layer and a second signal layer, wherein the first signal layer, the power layer, the ground layer, and the second signal layer are deployed in a top-down model, wherein the through hole further goes through the first signal layer and the second signal layer.

6. The PCB of claim 5, wherein each electrical conductor further comprises two pads with substantially same diameters, wherein the two pads are deployed on the first and second signal layers respectively; wherein the hollow main portion comprises a hollow columnar main portion; the extending portion comprises a central part with a ring-shape, a linking part, and an extending part, wherein the central part is located around the hollow columnar main portion, and has an outer diameter being substantially equal to an outer diameter of each of the two pads, wherein the linking part extends out from the central part, and wherein the extending part extends out from distal ends of the linking part, and is located on a circle having an outer diameter being greater than the diameter of the central part.

7. The PCB of claim 6, wherein the thickness of the extending part is substantially equal to the thickness of the power layer or the ground layer.

8. A printed circuit board (PCB) comprising:
a power layer;
a ground layer;
a through hole, wherein the through hole goes through the power layer and the ground layer; and
a conductor comprising a hollow main body formed in a bounding wall of the through hole, wherein the hollow main body is conductively connected to one of the power layer and the ground layer, and insulated from the other one of the power layer and the ground layer by an insulation area;
wherein the power layer and the ground layer comprise an extending portion extending into the insulation area; wherein the extending portion is insulated from the conductor, to increase an area of the power layer facing the ground layer.

9. The PCB of claim 8, wherein the through hole is a power through hole or a ground through hole.

10. The PCB of claim 8, wherein the extending portion are made of electrical material.

11. The PCB of claim 8, further comprising a first signal layer and a second signal layer, wherein the first signal layer, the power layer, the ground layer, and the second signal layer are deployed in a top-down model, wherein the through hole further goes through the first signal layer and the second signal layer.

12. The PCB of claim 9, wherein the conductor further comprises two pads with the substantially same outer diameters, wherein the two pads are deployed on the first and second signal layers respectively.
